(19) United States
(12) Patent Application Publication
(10) Pub. No.: US 2025/0226230 A1
(43) Pub. Date: Jul. 10, 2025

(54) SILICON POLISHING METHOD AND COMPOSITION FOR SILICON POLISHING

(71) Applicant: NORITAKE CO., LIMITED, Nagoya-shi, Aichi (JP)

(72) Inventors: Makoto SATO, Nagoya-shi (JP); Masatoshi KISHIMOTO, Nagoya-shi (JP)

(73) Assignee: NORITAKE CO., LIMITED, Nagoya-shi, Aichi (JP)

(21) Appl. No.: 18/847,502

(22) PCT Filed: Mar. 28, 2023
(86) PCT No.: PCT/JP2023/012682

§ 371 Date: Sep. 16, 2024

(30) Foreign Application Priority Data
Mar. 28, 2022 (JP) 2022-052600

(51) Int. Cl. H01L 21/306; B24B 37/04; B24B 37/24

(52) U.S. Cl. CPC H01L 21/30625; B24B 37/044; B24B 37/245

(57) ABSTRACT

A silicon polishing method and a silicon polishing composition that is to be used for the silicon polishing method. The silicon polishing method is for polishing a silicon wafer by using an abrasive-grain polishing pad that contains polishing abrasive grains while supplying the silicon polishing composition that does not contain the polishing abrasive grains. The silicon polishing composition contains an organic amine and a water. The silicon polishing composition has a pH of 10.6 to 12.8.

### TECHNICAL FIELD

The present invention relates to a silicon polishing method and a silicon-wafer polishing composition, which are used for polishing a surface of a silicon wafer known as a substrate of a semiconductor device, and relates to techniques for improving a polishing efficiency while reducing environmental impact.

### BACKGROUND ART

Conventionally, mirror polishing of a silicon wafer has been achieved by using a slurry-like polishing composition that contains silica abrasive grains as polishing abrasive grains, a polishing accelerator containing a basic compound, and a water. Such a polishing composition is described in Japan Patent No. 6960341.

Where the silicon wafer is polished in a polishing machine with use of a polishing pad (polishing cloth) in a state in which such a polishing composition is supplied, a large amount of used silica abrasive grains are discharged from the polishing machine, causing a high environmental impact. Further, the polishing accelerator contained in the polishing composition contains an amine compound that may contain a tetramethylammonium hydroxide (TMAH) known as a poisonous substance, thereby degrading a work environment.

### PRIOR ART DOCUMENTS

### Patent Documents

Patent Document 1: Japan Patent No. 6960341

### SUMMARY OF THE INVENTION

### Object to be Achieved by the Invention

On the other hand, attempts have been made to polish the silicon wafer by using an abrasive-grain polishing pad that discharges fewer abrasive grains, while supplying a polishing fluid (water), such that the silicon wafer is polished only by the polishing abrasive grains contained in the polishing pad. However, although the amount of used silica abrasive grains discharged from the polishing machine is reduced, the polishing efficiency (polishing rate) is low, and scratches caused by the polishing waste occur, so that a satisfactory polishing quality cannot be achieved.

The present invention was made in view of the background discussed above. It is therefore an object of the present invention to provide a silicon polishing method for polishing a silicon wafer by using an abrasive-grain polishing pad that discharges fewer abrasive grains so as to reduce an environmental impact, and also a silicon polishing composition that is to be used in the silicon polishing method, wherein the silicon polishing method makes it possible to increase a polishing efficiency of the abrasive-grain polishing pad while maintaining a polishing quality.

Having made various studies under the above-described situation, the present inventors found that it is possible to perform mirror polishing of the silicon wafer by using an abrasive-grain polishing pad with high efficiency by providing, on the abrasive-grain polishing pad, a silicon-wafer polishing composition that contains a substance that enhances a chemical reactivity with the silicon without using any poisonous or deleterious substances, as described below. That is, an alkaline agent was added to the silicon polishing composition to make it alkaline such that the silicon polishing composition would react easily with the silicon wafer, and an organic amine was added to the silicon polishing composition as needed as a substance that reacts with silicon. Although the organic amine alone may be added to a water to maintain its alkalinity, the alkaline agent was added to the water together with the organic amine so as to improve stability of the alkalinity. In this way, in the silicon polishing composition containing the organic amine and water or containing the organic amine, alkaline agent and water, piperazine, ethylenediamine, and diethylenetriamine were used as the organic amine, and quaternary amine similar to tetramethylammonium hydroxide and ammonia water, which is not a deleterious substance at a low concentration, were used as the alkaline agent.

### Measures for Solving the Problem

A gist of a first aspect of the invention is a silicon polishing method for polishing a silicon wafer by using an abrasive-grain polishing pad that contains polishing abrasive grains while supplying a silicon polishing composition that does not contain the polishing abrasive grains, wherein the silicon polishing composition contains an organic amine and a water, and the silicon polishing composition has a pH of 10.6 to 12.8.

A gist of a second aspect of the invention is, in the first aspect of the invention, the silicon polishing composition contains an inorganic alkaline agent in addition to the organic amine and the water, and the inorganic alkaline agent is ammonium hydroxide having a concentration not higher than 2.82 mol/l or potassium hydroxide having a concentration not higher than 0.93 mol/l.

A gist of a third aspect of the invention is, in the second aspect of the invention, the concentration of the inorganic alkaline agent is 0.030 to 0.100 mol/l.

A gist of a fourth aspect of the invention is, in any one of the first through third aspects of the invention, the organic amine is 0.025 to 0.100 mol/l.

A gist of a fifth aspect of the invention is, in any one of the first through fourth aspects of the invention, the organic amine is a substance having a primary amine and/or a secondary amine.

A gist of a sixth aspect of the invention is, in the fifth aspect of the invention, the organic amine is ethylenediamine, piperazine or diethylenetriamine.

A gist of a seventh aspect of the invention, in any one of the first through sixth aspects of the invention, the polishing abrasive grains contained in the abrasive-grain polishing pad are silica, ceria, zirconia, alumina and/or silicon carbide.

A gist of an eighth aspect of the invention is a silicon polishing composition, which is to be supplied onto an abrasive-grain polishing pad containing polishing abrasive grains when a silicon wafer is polished by using the abrasive-grain polishing pad, wherein the silicon polishing composition contains an organic amine and a water, and the silicon polishing composition has a pH of 10.6 to 12.8.

A gist of a ninth aspect of the invention is, in the eighth aspect of the invention, the silicon polishing composition contains an inorganic alkaline agent in addition to the organic amine and the water, and the inorganic alkaline agent is ammonium hydroxide having a concentration not higher than 2.82 mol/l or potassium hydroxide having a concentration not higher than 0.93 mol/l.

A gist of a tenth aspect of the invention is, in the ninth aspect of the invention, the concentration of the inorganic alkaline agent is 0.030 to 0.100 mol/l.

A gist of an eleventh aspect of the invention is, in any one of the eighth through tenth aspects of the invention, the organic amine is 0.025 to 0.100 mol/l.

A gist of a twelfth aspect of the invention is, in any one of the eighth through eleventh aspects of the invention, the organic amine is a substance having primary amine and/or secondary amine.

A gist of a thirteenth twelfth aspect of the invention is, in any one of the eighth through twelfth aspects of the invention, the organic amine is ethylenediamine, piperazine or diethylenetriamine.

### Effects of the Invention

The silicon polishing method according to the first aspect of the invention is for polishing the silicon wafer by using the abrasive-grain polishing pad that contains the polishing abrasive grains while supplying the silicon polishing composition that does not contain the polishing abrasive grains, wherein the silicon polishing composition contains the organic amine and the water, and the silicon polishing composition has the pH of 10.6 to 12.8. Thus, the reactivity with the silicon is 35 enhanced under a strong alkalinity of the organic amine, resulting in high polishing efficiency.

In the silicon polishing method according to the second aspect of the invention, the silicon polishing composition contains the inorganic alkaline agent in addition to the organic amine and the water, and the inorganic alkaline agent is the ammonium hydroxide having the concentration not higher than 2.82 mol/l or the potassium hydroxide having the concentration not higher than 0.93 mol/l. Thus, it is possible to maintain a stable and strong alkalinity, thereby further enhancing the reactivity with the silicon and resulting in higher polishing efficiency. At the same time, as the inorganic alkaline agent, the ammonium hydroxide having the concentration not higher than 2.82 mol/l (10%) that is below a range of the concentration considered to be deleterious, or the potassium hydroxide having the concentration not higher than 0.93 mol/l (5%) is used whereby risk is reduced in a polishing work environment.

In the silicon polishing method according to the third aspect of the invention, the concentration of the inorganic alkaline agent is 0.030 to 0.100 mol/l. Thus, since a stable strong alkalinity is maintained, the reactivity with the silicon is further enhanced, thereby resulting in higher polishing efficiency while simultaneously reducing the risk in the polishing work environment.

In the silicon polishing method according to the fourth aspect of the invention, the organic amine is 0.025 to 0.100 mol/l. Thus, the reactivity with the silicon is enhanced under the strong alkalinity of the organic amine, thereby resulting in high polishing efficiency.

In the silicon polishing method according to the fifth aspect of the invention, the organic amine is the substance having the primary amine and/or the secondary amine. Thus, the organic amine becomes strongly alkaline when being dissolved in water.

In the silicon polishing method according to the sixth aspect of the invention, the organic amine is ethylenediamine, piperazine or diethylenetriamine. Thus, the organic amine becomes strongly alkaline when being dissolved in water.

In the silicon polishing method according to the seventh aspect of the invention, the polishing abrasive grains contained in the abrasive-grain polishing pad are silica, ceria, zirconia, alumina and/or silicon carbide. Thus, an appropriate polishing efficiency can be obtained.

The silicon polishing composition according to the eighth aspect of the invention is to be supplied onto the abrasive-grain polishing pad containing polishing abrasive grains when the silicon wafer is polished by using the abrasive-grain polishing pad, wherein the silicon polishing composition contains the organic amine and the water, and the silicon polishing composition has the pH of 10.6 to 12.8. Thus, the reactivity with the silicon is enhanced under a strong alkalinity of the organic amine, resulting in high polishing efficiency.

In the silicon polishing composition according to the ninth aspect of the invention, the silicon polishing composition contains the inorganic alkaline agent in addition to the organic amine and the water, and the inorganic alkaline agent is the ammonium hydroxide having the concentration not higher than 2.82 mol/l or the potassium hydroxide having the concentration not higher than 0.93 mol/l, thereby increasing polishing efficiency for the silicon. Thus, it is possible to maintain a stable and strong alkalinity, thereby further enhancing the reactivity with the silicon and resulting in higher polishing efficiency. At the same time, as the inorganic alkaline agent, the ammonium hydroxide having the concentration not higher than 2.82 mol/l (10%) that is below a range of the concentration considered to be deleterious, or the potassium hydroxide having the concentration not higher than 0.93 mol/l (5%) is used whereby risk is reduced in a polishing work environment.

In the silicon polishing composition according to the tenth aspect of the invention, the concentration of the inorganic alkaline agent is 0.030 to 0.100 mol/l. Thus, since a stable strong alkalinity is maintained, the reactivity with the silicon is further enhanced, thereby resulting in higher polishing efficiency while simultaneously reducing the risk in the polishing work environment.

In the silicon polishing composition according to the eleventh aspect of the invention, the organic amine is 0.025 to 0.100 mol/l. Thus, the reactivity with the silicon is enhanced under the strong alkalinity of the organic amine, thereby resulting in high polishing efficiency.

In the silicon polishing composition according to the twelfth aspect of the invention, the organic amine is the substance having the primary amine and/or the secondary amine. Thus, the organic amine becomes strongly alkaline when being dissolved in water.

In the silicon polishing composition according to the thirteenth aspect of the invention, the organic amine is ethylenediamine, piperazine or diethylenetriamine. Thus, the organic amine becomes strongly alkaline when being dissolved in water.

### BRIEF DESCRIPTION OF DRAWINGS

FIG. 1 A perspective view conceptually showing a construction of a polishing machine for carrying out a polishing method according to an embodiment of the present invention.

FIG. 2 A plan view schematically showing a rotation mechanism of a holding disc of the polishing machine shown in FIG. 1.

FIG. 3 A schematic view showing, in enlargement, a surface texture of a polishing pad shown in FIG. 1.

FIG. 4 A view showing a chemical structure of a primary amine (ethylenediamine), which is an example of an organic amine contained in a polishing fluid used in the polishing method shown in FIG. 1.

FIG. 5 A view showing a chemical structure of a secondary amine (piperazine), which is an example of the organic amine contained in the polishing fluid used in the polishing method shown in FIG. 1.

FIG. 6 A view showing a chemical structure of a substance (diethylenetriamine) that has the primary amine and the secondary amine, which is an example of the organic amine contained in the polishing fluid used in the polishing method shown in FIG. 1.

FIG. 7 A view showing a chemical structure of ammonium hydroxide, which is an example of an inorganic alkaline agent contained in the polishing fluid used in the polishing method shown in FIG. 1.

FIG. 8 A view showing a chemical structure of potassium hydroxide, which is an example of the inorganic alkaline agent contained in the polishing fluid used in the polishing method shown in FIG. 1.

FIG. 9 A diagram showing a type of the polishing pad, a composition of the polishing fluid, a hydrogen ion concentration pH and polishing test results (polishing rate PR (nm/min) and surface roughness Sa (nm) of a polished surface) in each of comparative example methods 01-08 and example methods 01-13 in polishing tests conducted by inventors of the present invention.

FIG. 10 A bar graph showing a relationship between a difference in a concentration (mol/l) of the organic amine contained in the polishing fluid and the polishing rate PR, using data shown in FIG. 9.

FIG. 11 A bar graph showing a relationship between a difference in the concentration (mol/l) of the organic amine contained in the polishing fluid and a surface roughness Sa (nm) of the polished surface, using the data shown in FIG. 9.

FIG. 12 A line graph showing the relationship between the difference in the concentration (mol/l) of the organic amine contained in the polishing fluid and the polishing rate, using the data shown in FIG. 9.

FIG. 13 A line graph showing the relationship between the difference in the concentration (mol/l) of the organic amine contained in the polishing fluid and the surface roughness Sa (nm) of the polished surface, using the data shown in FIG. 9.

FIG. 14 A line graph showing a relationship between a concentration (mol/l) of piperazine as the organic amine contained in the polishing fluid and the polishing rate, using the data shown in FIG. 9.

FIG. 15 A line graph showing a relationship between the concentration (mol/l) of the piperazine as the organic amine contained in the polishing fluid and the surface roughness Sa, using the data shown in FIG. 9.

FIG. 16 A diagram showing a change of the polishing rate PR due to difference in the concentration (mol/l) of the inorganic alkaline agent in the polishing fluid, using the data shown in FIG. 9.

FIG. 17 A diagram showing a change of the surface roughness Sa of the polished surface due to difference in the concentration (mol/l) of the inorganic alkaline agent in the polishing fluid, using the data shown in FIG. 9.

FIG. 18 A bar graph showing effect of difference in the concentration (mol/l) of the organic amine and the inorganic alkaline agent contained in the polishing fluid on the polishing rate PR for each silica and ceria, from the data shown in FIG. 9.

FIG. 19 A bar graph showing effect of difference in the concentration (mol/l) of the organic amine and the inorganic alkaline agent contained in the polishing fluid on the surface roughness Sa of the polished surface for each silica and ceria, from the data shown in FIG. 9.

FIG. 20 A diagraph showing a relationship between the pH of the polishing fluid and the polishing rate PR, from the data shown in FIG. 9.

FIG. 21 A diagraph showing a relationship between the pH of the polishing fluid and the surface roughness Sa, from the data shown in FIG. 9.

FIG. 22 A schematic view showing a polishing mechanism when a workpiece is polished on a polishing plate by using a slurry containing polishing abrasive grains.

FIG. 23 A schematic view showing a polishing mechanism when a workpiece is polished on an abrasive-grain-fixed polishing pad on which the polishing abrasive grains are fixed.

FIG. 24 A schematic view showing a polishing mechanism when a workpiece is polished on a polishing pad made of nonwoven fabric.

FIG. 25 A microscopic photograph showing an example of the polishing pad shown in FIG. 1.

FIG. 26 A schematic view showing a polishing mechanism when a workpiece is polished on a polishing pad.

### MODE FOR CARRYING OUT THE INVENTION

Hereinafter, there will be described an embodiment of the present invention, in detail with reference to the drawings.

### Embodiment

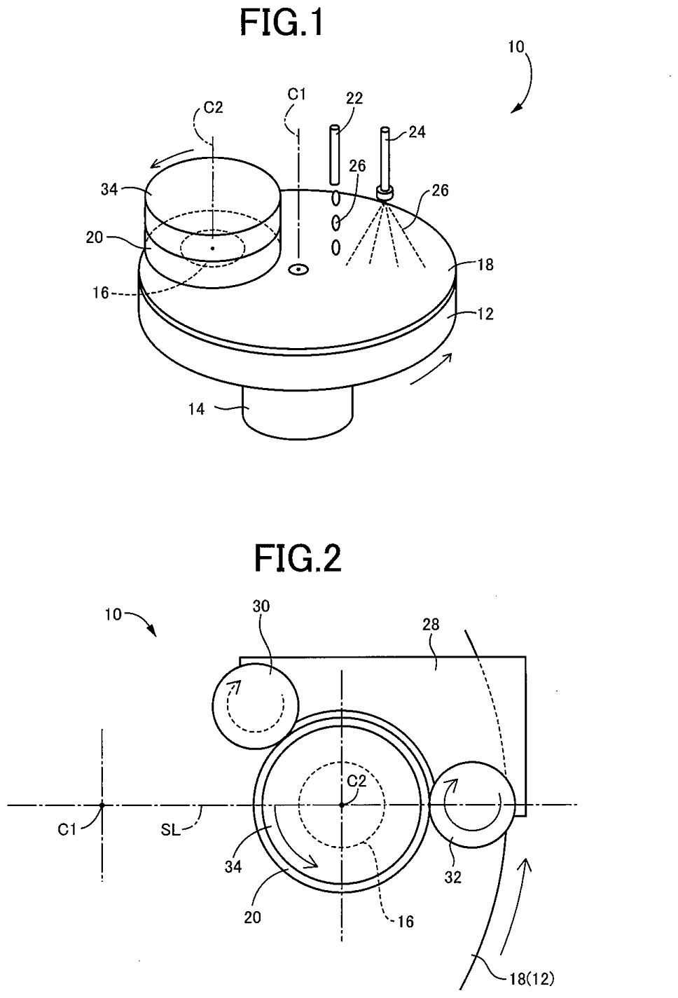

FIG. 1 conceptually shows main parts of a flat surface polishing machine for carrying out a silicon polishing method according to an embodiment of the present invention, with a guide-roller holder base being removed. In FIG. 1, the flat surface polishing machine 10 is provided with a polishing plate 12 supported so as to be rotatable about its vertical rotation axis C1, and the polishing plate 12 is driven and rotated by a plate drive motor 14 at a constant speed in one direction indicated by an arrow in FIG. 1. A polishing pad 18 is attached to an upper surface of the polishing plate 12, i.e., a surface against which a workpiece (silicon wafer) 16 is pressed.

The workpiece 16 is held on a lower surface of a holding disc 20, i.e., a surface of the holding disc 20 opposed to the polishing pad 18, and the holding disc 20 presses the workpiece 16 against the polishing pad 18 with a predetermined load. Further, a dripping nozzle 22 and a spray nozzle 24 are provided in vicinity of the holding disc 20 of the flat surface polishing machine 10, and a polishing fluid (lubricant) 26, which is an alkaline aqueous solution, is supplied onto the polishing plate 12 from a tank (not shown).

In addition, the flat surface polishing machine 10 is provided with an adjustment-tool holding member (not shown) that is rotatable around a rotation axis parallel to the rotation axis C1 of the polishing plate 12 and movable in a direction of the rotation axis C1 and in a radial direction of the polishing plate 12, and an abrasive-body adjustment tool (dresser or conditioner) such as a diamond wheel (not shown) that is attached to a lower surface of the adjustment-tool holding member, i.e., a surface of the adjustment-tool holding member opposed to the polishing pad 18, as needed. This adjustment-tool holding member and the abrasive-body adjustment tool attached thereto are pressed against the polishing pad 18 while being rotated and driven by an adjustment tool driving motor (not shown), and are moved back and forth in a radial direction of the polishing plate 12, thereby adjusting a polishing surface of the polishing pad 18 and constantly maintaining a surface condition of the polishing pad 18 in a state suitable for polishing.

As shown in FIG. 2, in a position deviated from the rotation axis C1 on the polishing plate 12, an outer circumferential surface of the short-cylindrical shaped holding disc 20, which holds the workpiece 16 to be polished on its lower surface by suction, adhesion or a holding frame, is supported by a pair of guide rollers 30, 32 (i.e., an idle guide rollers 30 and a drive guide rollers 32) provided on a guide-roller holder base 28, which is fixed in a position fixed to a frame (not shown), such that the holding disc 20 is rotatable around a rotation axis C2. The holding disc 20 is rotated around the rotation axis C2 by a rotational force based on a difference in a peripheral speed of the polishing plate 12 or polishing pad 18, while the holding disc 20 is pressed against the polishing pad 18 on the polishing plate 12 by the load of, for example, a weight 34, so that the workpiece 16 is polished.

In addition, the flat surface polishing machine 10 is provided with an adjustment-tool holding member (not shown) that is rotatable around a rotation axis parallel to the rotation axis C1 of the polishing plate 12 and movable in a direction of the rotation axis C1 and in a radial direction of the polishing plate 12, and an abrasive-body adjustment tool (conditioner) such as a diamond wheel (not shown) that is attached to a lower surface of the adjustment-tool holding member, i.e., a surface of the adjustment-tool holding member opposed to the polishing pad 18, as needed. This adjustment-tool holding member and the abrasive-body adjustment tool attached thereto are pressed against the polishing pad 18 while being rotated and driven by an adjustment tool driving motor (not shown), and are moved back and forth in a radial direction of the polishing plate 12, thereby adjusting the polishing surface of the polishing pad 18 and constantly maintaining a surface condition of the polishing pad 18 in a state suitable for polishing.

The following polishing method is applied when polishing with the polishing machine 10. That is, the polishing plate 12 and the polishing pad 18 attached thereto are rotated around the rotation axis C1 by the plate drive motor 14, the holding disc 20 and the workpiece (silicon wafer) 16 held on the lower surface thereof are rotated around the rotation axis C2 by the drive guide roller 32, the polishing fluid 26 that does not contain polishing abrasive grains is supplied onto the surface of the polishing pad 18 from the dripping nozzle 22 and the spray nozzle 24, and the workpiece 16 held on the holding disc 20 is pressed against the polishing pad 18. As a result, a polished surface of the workpiece 16, i.e., a surface of the workpiece 16 opposed to the polishing pad 18, is polished flat by a chemical polishing action of the polishing fluid 26 and by a mechanical abrasive action of the polishing abrasive grains contained in the polishing pad 18 and supplied from the polishing pad 18. The polishing abrasive grains 36 are made of silica having an average grain size of about 80 nm.

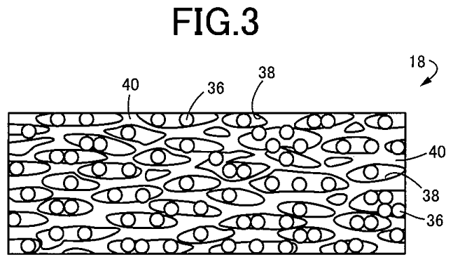

The polishing pad 18 attached on the polishing plate 12 is an abrasive-grain polishing pad (LHA pad) made of epoxy resin or PES resin having independent 35 pores or communication pores 38 housing the polishing abrasive grains 36 as shown in FIG. 3, and has dimensions of, for example, about 300 (mm) in outside diameter and 5 (mm) in thickness.

The polishing pad 18 is formed in a disc shape with a base material resin made of epoxy resin or PES resin in which independent pores or communication pores 38 are formed, and a large number of polishing abrasive grains 36 that are filled in the communication pores 38 of the base material resin 40, some of which are fixed to the base material resin 40, or some of which are separated from the base material resin during polishing. Therefore, the polishing pad 18 is called a semi-fixed abrasive-grain polishing pad that contains the polishing abrasive grains 36, and polishing using this abrasive-grain polishing pad is called a semi-fixed abrasive polishing. This polishing pad 18 is composed of, for example, about 32 volume % of polishing abrasive grains 36, about 33 volume % of base material resin 40 and communication pores 38 that occupy the remaining volume. The communication pores 38 of the base material resin 40, which are formed in a pongee or mesh shape, are formed to be equal to or larger than the polishing abrasive grains 36, and a large number of the polishing abrasive grains 36 are held within the communication pores 38. The base material resin 40 and each of the polishing abrasive grains 36 are fixed to each other with a necessary and sufficient bonding force. In the present embodiment, the polishing pad 18 enables polishing of the workpiece (silicon wafer) 16 by the mechanical polishing action of the polishing abrasive grains 36 supplied by the polishing pad 18 itself, without using a slurry containing colloidal silica, for example, and the chemical polishing action of the highly alkaline polishing fluid 26 that does not contain polishing abrasive grains.

The polishing abrasive grains 36 are preferably silica, but other polishing abrasive grains, such as those containing ceria, alumina, zirconia, silicon carbide, titania, manganese compounds, barium carbonate, chromium oxide and/or iron oxide, may also be used. As the above-described silica, for example, fumed silica (fine silica grains obtained by burning silicon tetrachloride, chlorosilane, etc. at a high temperature in presence of hydrogen and oxygen) is preferably used. An average grain size of the polishing abrasive grains 26 is preferably 0.005 to 3.0 (μm), more preferably 0.005 to 1.0 (μm), more preferably 0.02 to 0.6 (μm), more preferably 0.08 to 0.5 (μm), and even more preferably 0.08 to 0.3 (μm). For example, if the average grain size of the polishing abrasive grains 36 is larger than 3.0 (μm), polishing scratches are likely to occur on the workpiece 16 due to the polishing abrasive grains 26 that are liberated from the base material resin 40 during a polishing process described below. Furthermore, if the average grain size of the polishing abrasive grains 36 is smaller than 0.005 (μm), the polishing abrasive grains 36 tend to aggregate, and the polishing scratches are likely to occur on the workpiece during the polishing process.

The grain size of the polishing abrasive grains 36 is measured by a laser diffraction/scattering method, for example, by a grain size/granularity distribution measuring device, Microtrack MT3300, manufactured by Nikkiso Co., Ltd., and the average grain size is an arithmetic mean of the grain size. Grain sizes below a measurement limit of the above laser diffraction/scattering method are measured by a dynamic light scattering method, for example, by a grain size/granularity distribution measuring device, Nanotrack UPA-EX250, manufactured by Nikkiso Co., Ltd.

The polishing fluid 26 corresponds to a polishing composition for silicon, contains an organic amine for increasing alkalinity and water, is highly alkaline (pH=10.6-12.8) to increase reactivity with the workpiece (silicon wafer) 16 and to promote the chemical polishing action, and does not contain (loose) polishing abrasive grains. The organic amine is preferably 0.025-0.100 mol/l.

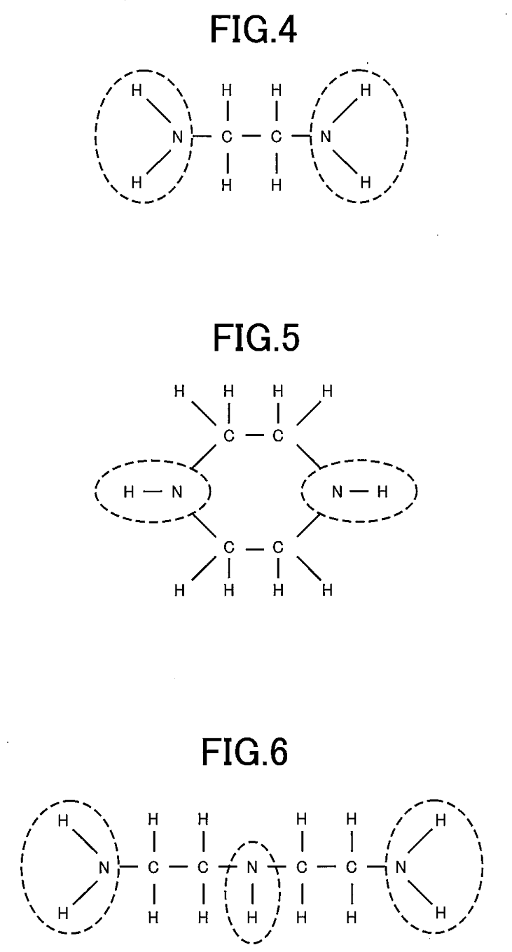

As the above-described organic amine, a primary amine such as ethylenediamine having the chemical structure shown in FIG. 4, a secondary amine such as piperazine having the chemical structure shown in FIG. 5, or a substance having a primary amine and a secondary amine such as diethylenetriamine having the chemical structure shown in FIG. 6 is preferably used. The parts surrounded by dashed lines in FIG. 4, FIG. 5 and FIG. 6 indicate amino groups.

In addition to the organic amine and the water, the polishing fluid 26 also contains an inorganic alkaline agent in order to make it even more stable and highly alkaline. The inorganic alkaline agent is ammonium hydroxide with a concentration of 2.82 mol/l (10%) or less, or potassium hydroxide with a concentration of 0.93 mol/l (50%) or less, so as to be below the range of deleterious substances. Preferably, the concentration of the inorganic alkaline agent is 0.030 to 0.100 mol/L.

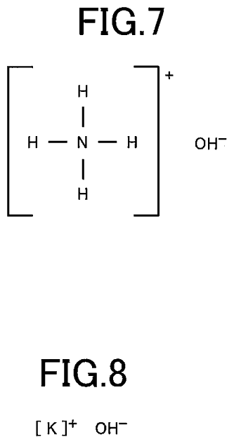

As the above-described inorganic alkaline agent, for example, ammonium hydroxide shown in FIG. 7 or potassium hydroxide shown in FIG. 8 is preferably used.

### Experimental Example

There will be described an experimental example conducted by the inventors. First, using an apparatus constructed similarly to the polishing machine 10 shown in FIG. 1, a loose abrasive polishing using a nonwoven pad and a silica-containing (40 wt %) slurry, and a semi-fixed abrasive polishing using a polishing pad containing silica abrasive grains or a pad containing ceria abrasive grains and 21 types of polishing fluid adjusted to have different components and pH, was performed in a polishing test under polishing test conditions indicated below, for a common sample to be polished, wherein the common sample is a silicon single crystal plate having a diameter of 4 inches and a thickness of 350 μm. The polishing rate PR and the surface roughness Sa of the silicon wafer after the polishing test were measured by using a polishing rate measurement method and a surface roughness measurement method that are described below.

### [Polishing Test Conditions]

Flat surface polishing machine: modified LAPMASTER LP15 (3-axis polishing machine)
Workpiece: silicon wafer <100> having diameter of 4 inches
Workpiece rotation speed: 60 rpm
Polishing pad/polishing fluid: non-woven pad/silica slurry (40 wt %)
Polishing pad/polishing fluid: pad containing silica abrasive grains/polishing fluid
Polishing pad/polishing fluid: pad containing ceria abrasive grains/polishing fluid
Polishing pad diameter: 300 mm
Polishing pad rotation speed: 60 rpm
Polishing pressure: 10.1 kPa
Distance between center of polishing pad and center of workpiece: 85 mm
Polishing fluid flow rate: 10 ml/min
Dressing pressure, rotation speed, time: 25 kPa, 60 rpm, 120 sec

### [Method of Measuring Polishing Rate]

A mass difference of the silicon wafer before and after the polishing test was measured by using an analytical balance, and an amount of polishing (abrasion thickness) was calculated from a known density of the silicon wafer and a surface area of the polishing surface. Then, the polishing rate PR (nm/min) was calculated by dividing the amount of polishing by a polishing time.

### [Surface Roughness Measurement Method]

The surface roughness of the polished surface of the silicon wafer after the polishing test was measured by using a white-light interference microscope (Hitachi High-Tech Corporation VS-1330), and an arithmetic mean roughness Sa defined in ISO25178 was calculated.

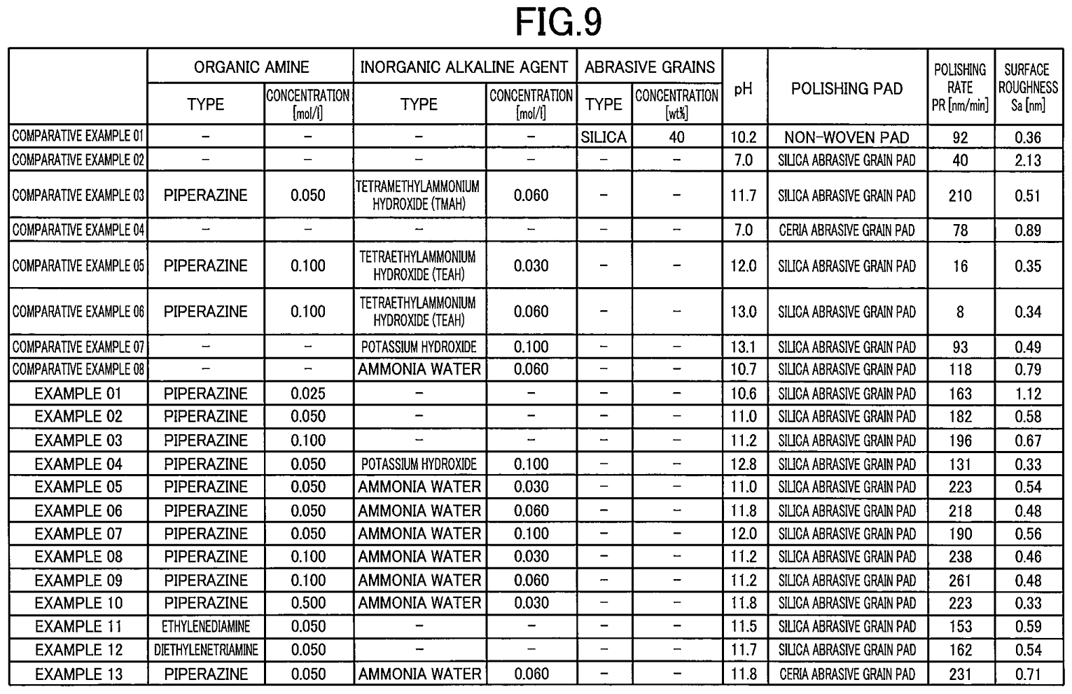

FIG. 9 shows type of the polishing pad, composition of the polishing fluid, hydrogen ion concentration pH and polishing test results (polishing rate PR (nm/min) and surface roughness Sa (nm) of the polished surface) for each of eight polishing methods as comparative example methods 01-08 and thirteen polishing methods as example methods 01-13. In the following, the polishing rate PR (nm/min) and the surface roughness Sa (nm) of the polished surface for each of the comparative example methods 01-08 and example methods 01-13 shown in FIG. 9 are analyzed. The comparative example methods 01-02 and 04-08 are in an unacceptable polishing group with low polishing rates PR lower than 120, while the example methods 01-13 are in an acceptable polishing group with high polishing rates PR not lower than 120. The comparative example method 03 has a high polishing rate PR not lower than 120, but is in the unacceptable polishing group because the inorganic alkaline agent contained in the polishing fluid used is tetramethylammonium hydroxide (TMAH), which is a deleterious substance, so it is classified as a non-qualified polishing process.

The concentration of the organic amine in the polishing fluid of example methods 01-13 shown in FIG. 9 is 0.025 to 0.100 mol/l, and it is considered to be highly alkaline (pH=10.6 to 12.8).

In FIG. 9, the polishing rate PR obtained by the comparative example methods 01-02 and 04-08 was 118 nm/min as the maximum, while the polishing rate PR obtained by the example methods 01-13 was 131 nm/min as the minimum. As a result, if the concentration of the organic amine is 0.025 to 0.100 mol/l, and the polishing fluid is made of the organic amine and water, or the organic amine, inorganic alkaline agent and water, it is possible to obtain a higher polishing rate PR than in the comparative example methods. It is noted that a high polishing rate PR is obtained in the comparative example method 03, but the comparative example method 03 is excluded from consideration because the inorganic alkaline agent contained in it is 20) tetramethylammonium hydroxide (TMAH) as a hazardous substance.

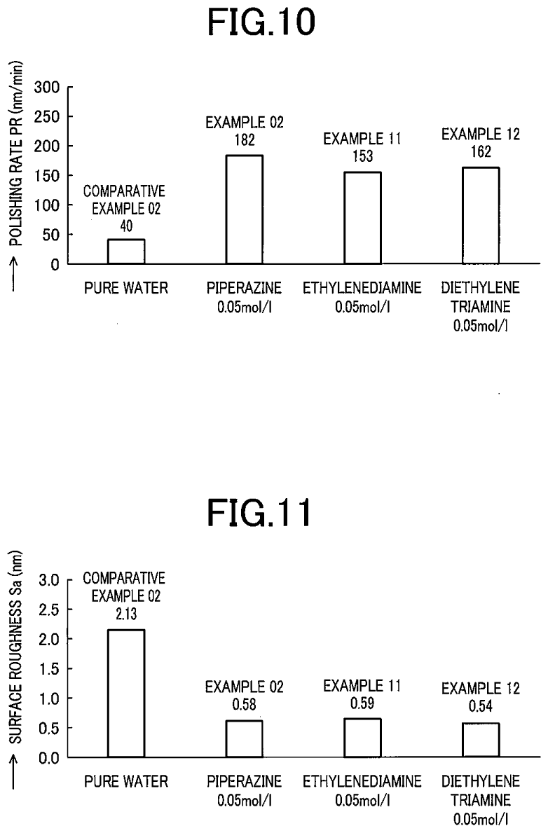

FIG. 10 is a bar graph showing a relationship between a difference in the concentration (mol/l) of the organic amine contained in the polishing fluid and the polishing rate PR, by using data in the comparative example method 02, example method 02, example method 11 and example method 12. As is clear from FIG. 10, as compared to the comparative example method 02 in which the difference in the concentration of the organic amine contained in the polishing fluid (pure water) is 0 mol/l and the pH is 7.0, a polishing rate PR that is about four times higher was obtained in the example methods 02, 11 and 12 in which the difference in the concentration of the organic amine contained in the polishing fluid is 0.50 mol/l and the pH is 11 or higher.

FIG. 11 is a bar graph showing a relationship between the difference in the concentration (mol/l) of the organic amine contained in the polishing fluid and the surface roughness Sa (nm) of the polished surface, by using data in the comparative example method 02, example method 02, example method 11 and example method 12. As is clear from FIG. 11, as compared to the comparative example method 02 in which the difference in the concentration of the organic amine contained in the polishing fluid (pure water) is 0 mol/l and the pH is 7.0, a surface roughness Sa of approximately 1/3.6 or less was obtained in the example methods 02, 11 and 12 in which the difference in the concentration of the organic amine contained in the polishing fluid is 0.50 mol/l and the pH is 11 or higher.

As is clear from FIG. 10 and FIG. 11, in the example methods 01-13, all organic amines have effect of improving the polishing rate PR and effect of reducing the surface roughness Sa of the polished surface.

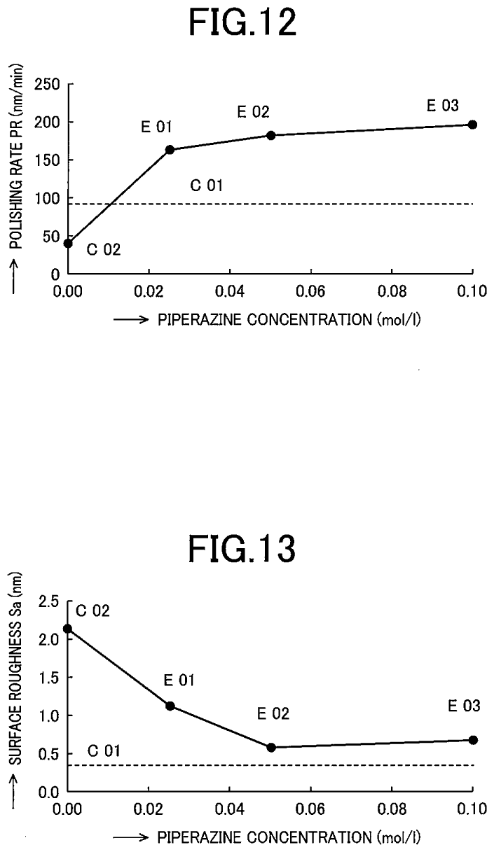

FIG. 12 and FIG. 13 show that, although the polishing fluid does not contain an organic alkaline agent, the piperazine alone can improve the polishing rate PR as long as the piperazine is 0.025 mol/l or more, and the piperazine alone can reduce the surface roughness Sa of the polished surface as long as the piperazine content is 0.050 mol/l or more.

FIG. 12 shows a relationship between the difference in the concentration (mol/l) of the organic amine contained in the polishing fluid and the polishing rate, for example, by using data in the comparative example method 02, example method 01, example method 02 and example method 03. As is clear from FIG. 12, as compared with the comparative example method 02 in which the difference in the concentration of the organic amine contained in the polishing fluid (pure water) is 0 mol/l and the pH is 7.0, a polishing rate PR that is about four times higher was obtained in the example methods 01, 02 and 03 in which, where the polishing fluid does not contain the inorganic alkaline agent but contains the organic amine alone, the difference in the concentration of the organic amine contained in the polishing fluid is 0.250 mol/l and the pH is 10.6 or higher.

FIG. 13 shows a relationship between the difference in the concentration (mol/l) of the organic amine contained in the polishing fluid and the surface roughness Sa (nm) of the polished surface, by using data in the comparative example method 02, example method 01, example method 02 and example method 03. As is clear from FIG. 13, as compared with the comparative example method 02 in which the difference in the concentration of the organic amine contained in the polishing fluid (pure water) is 0 mol/l and the pH is 7.0, a surface roughness Sa of approximately 1/1.9 or less was obtained in the example methods 01, 02 and 03 in which, where the polishing fluid does not contain the inorganic alkaline agent but contains the organic amine alone, the difference in the concentration of the organic amine is 0.250 mol/l or more and the pH is 10.6 or more.

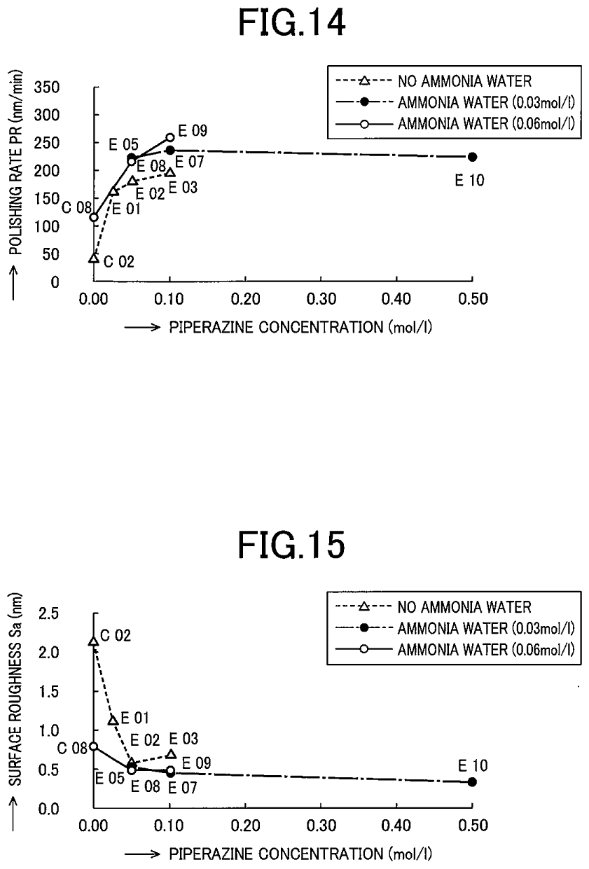

FIG. 14 and FIG. 15 show that the polishing rate can be improved as the concentration (mol/l) of piperazine as the organic amine contained in the polishing fluid is increased, and the addition of ammonia water as the inorganic alkaline agent, has the effect of reducing the surface roughness Sa and increasing the polishing rate PR.

The relationship between the concentration (mol/l) of piperazine as the organic amine contained in the polishing fluid and the polishing rate, which is shown in FIG. 14, and the relationship between the concentration (mol/l) of piperazine as the organic amine contained in the polishing fluid and the surface roughness Sa, which is shown in FIG. 15, are shown by using data in the comparative example method 02, comparative example methods 08, example method 01, example method 02, example method 03, example method 05, example method 07, example method 08, example method 09 and example method 10.

In FIG. 14, as the concentration (mol/l) of piperazine contained in the polishing fluid is increased, the polishing rate PR is increased and reaches saturation. Further, as the concentration (mol/l) of ammonia contained in the polishing fluid is increased, the polishing rate PR is increased. In FIG. 15, as the concentration (mol/l) of piperazine contained in the polishing fluid is increased, the surface roughness Sa of the polished surface is reduced and reaches saturation. Further, as the concentration (mol/l) of ammonia contained in the polishing fluid is increased, the surface roughness Sa of the polished surface is reduced.

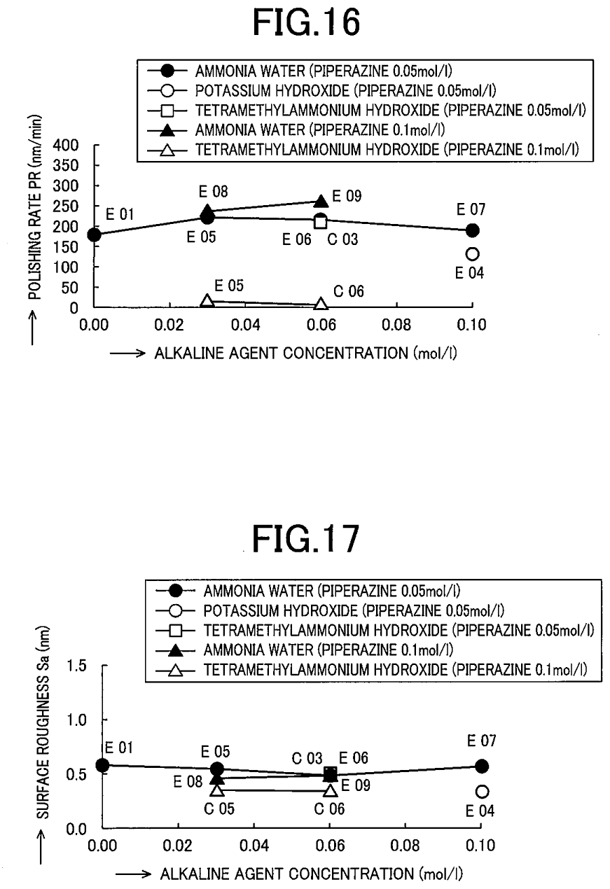

FIG. 16 shows a change of the polishing rate PR due to differences in the concentration (mol/l) of the inorganic alkaline agent in the polishing fluid, and FIG. 17 shows a change of the surface roughness Sa of the polished surface due to differences in the concentration (mol/l) of the inorganic alkaline agent in the polishing fluid. In FIG. 16 and FIG. 17, ammonia water and tetramerammonium hydroxide have effect of improving the polishing rate PR. In contrast, tetraethylammonium hydroxide significantly reduces the polishing rate PR, and potassium hydroxide also reduces the polishing rate PR. However, the tetraethylammonium hydroxide and the potassium hydroxide have effect of improving the surface roughness Sa.

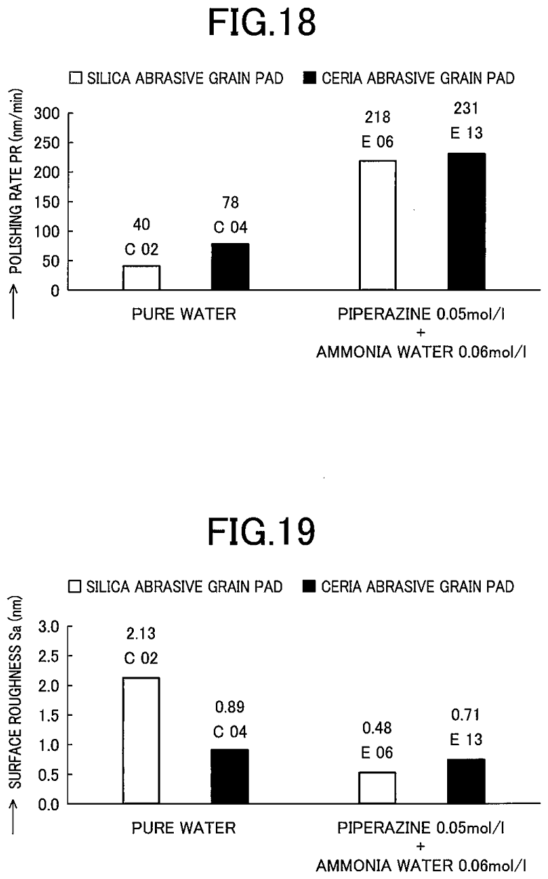

FIG. 18 is a bar graph showing effect of difference in the concentration (mol/l) of the organic amine and the inorganic alkaline agent contained in the polishing fluid on the polishing rate PR for each silica and ceria. Further, FIG. 19 is a bar graph showing effect of difference in the concentration (mol/l) of the organic amine and the inorganic alkaline agent contained in the polishing fluid on the surface roughness Sa of the polished surface for each silica and ceria. As is clear from FIG. 18 and FIG. 19, whether the polishing abrasive grains are silica or ceria, the increase of the 35 concentration of piperazine in the polishing fluid has the same effect of increasing the polishing rate PR and decreasing the surface roughness Sa.

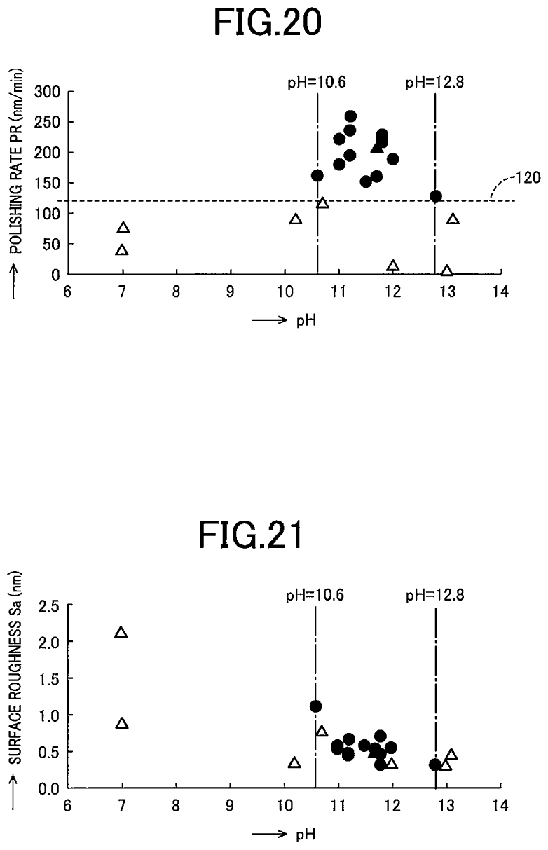

FIG. 20 shows a relationship between the pH of the polishing fluid and the polishing rate PR based on the data in FIG. 9, and FIG. 21 shows a relationship between the pH of the polishing fluid and the surface roughness Sa of the polished surface based on the data in FIG. 9. In FIG. 20 and FIG. 21, the example methods 01-13, each of which provide a polishing rate PR of 120 or higher, are indicated with ⊙, the comparative example methods 01 to 02 and 04 to 08, each of which provides a polishing rate PR of less than 120, are indicated with Δ, and the comparative example method 03 is indicated with ▴. FIG. 20 shows that the polishing rate PR peaks at a pH of around 11 to 12. FIG. 21 shows that each of the example methods 01 to 13 has a pH in the range of 10.6 to 12.8, and that the higher the pH, the lower the surface roughness Sa of the polished surface.

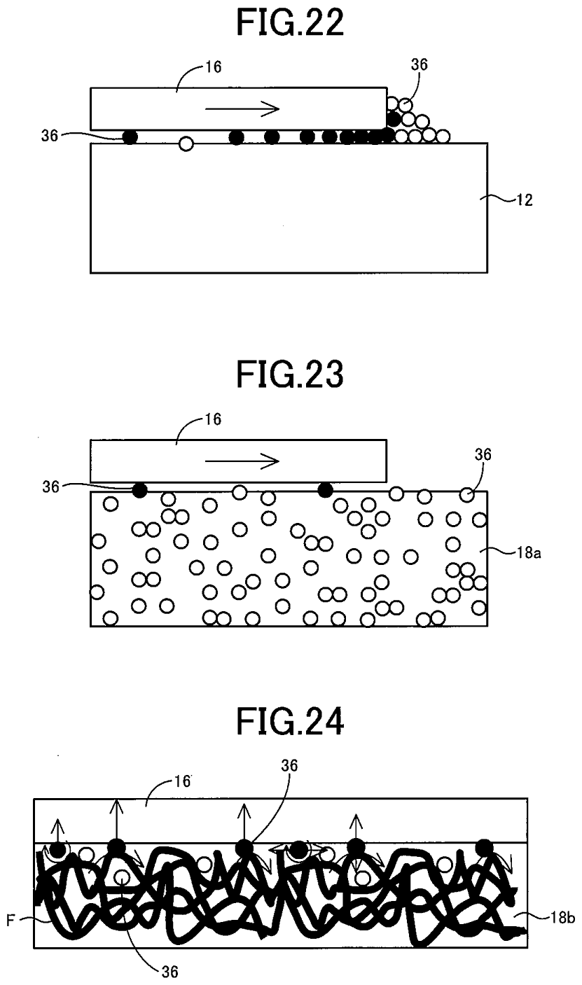

FIG. 22 is a view schematically showing a polishing mechanism in a case of a loose abrasive polishing in which the workpiece 16 is polished on a hard polishing pad or polishing plate 12 by using a slurry containing the polishing abrasive grains 36. In this case, the number of active abrasive grains, which are indicated by ●, is greater than the number of inactive abrasive grains, which are indicated by ◯, and the polishing abrasive grains 36 are rotated and act on the entire surface, so the polishing rate PR is high, but it is difficult to obtain a high flatness due to the uneven distribution of the active abrasive grains. In addition, many of the polishing abrasive grains 36, which are indicated by ◯, do not contribute to polishing, and the amount of polishing abrasive grains 36 discharged is large, so that the environmental impact is high.

FIG. 23 is a view schematically showing a polishing mechanism when the workpiece 16 is polished on a fixed-abrasive polishing pad 18a in which the polishing abrasive grains 36 are fixed directly in the non-foaming base material resin 40. In this case, supply of the polishing abrasive grains 36 from the fixed-abrasive polishing pad 18a is small, and the number of abrasive grains acting on polishing, which are indicated with ●, is small, so that the environmental impact is low. However, since the polishing abrasive grains 36, which are the acting abrasive grains contributing to polishing and which are indicated with ●, are not rotated, they only act on one point on a surface of the polishing abrasive grains 36, so that there are few points of action and the polishing rate PR is low. In addition, since the polishing abrasive grains 36 are not rotated, the workpiece 16 is easily scratched.

FIG. 24 is a view schematically showing a polishing mechanism when the workpiece 16 is polished on a nonwoven-fabric polishing pad 18b in which relatively rigid resin fibers F are bonded together in a meandering manner. In this case, the polishing abrasive grains 36, which are the active abrasive grains that contribute to polishing and are housed in spaces between the resin fibers and which are indicated with ●, can be moved in all directions including also a vertical direction (that is perpendicular to the polishing surface). When the polishing abrasive grains 36 on the surface of the polishing pad 18b climb over protruding parts of the polishing pad 18b, a large load is applied to the workpiece 16, thereby easily making the workpiece 16 get scratched.

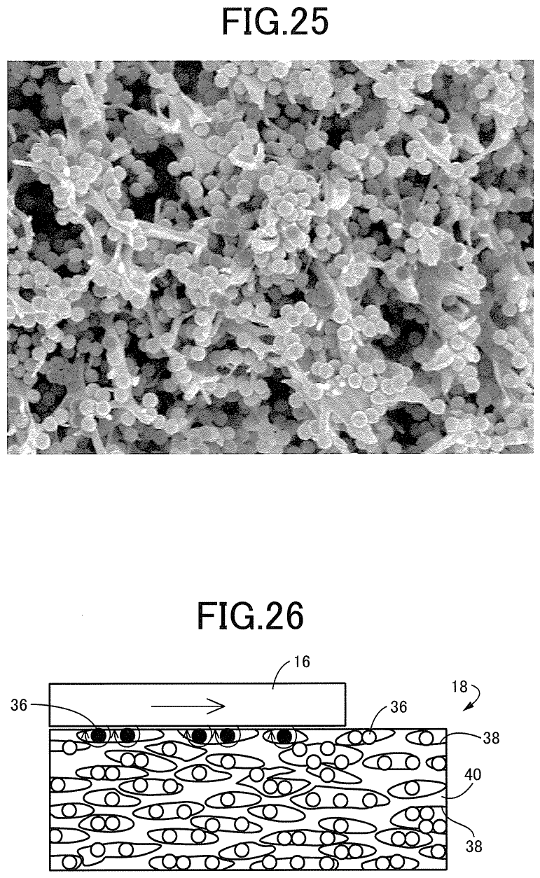

FIG. 25 is a microscopic photograph showing the semi-fixed abrasive-grain polishing pad 18 of the embodiment described above, and FIG. 26 is a schematic view showing a polishing mechanism when the workpiece 16 is polished on the polishing pad 18. In FIG. 26, the polishing abrasive grains 36 are relatively loosely housed in the communication pores 38 formed in the base material resin 40, and supply of the polishing abrasive grains 36 from the polishing pad 18a is moderately large. The polishing abrasive grains 36, which are the active abrasive grains that contribute to polishing and which are indicated with ●, are moved mainly in a horizontal direction (parallel to the polishing surface) and rotated during polishing, with little movement in the vertical direction (perpendicular to the polishing surface). During polishing, the polishing process progresses as the polishing abrasive grains 36 are rotated, and the polishing abrasive grains 36 are moved little in the vertical direction (perpendicular to the polishing surface). Thus, the polishing abrasive grains 36 remain in the communication pores 38 until the workpiece 16 passes, and a large load is not applied to the workpiece 16, so that the workpiece 16 is less likely to be scratched.

As described above, in the polishing method of the present embodiment and the polishing fluid 26 used for the polishing method, when the workpiece (silicon wafer) 16 is polished by using the polishing pad 18 as the abrasive-grain polishing pad that contains the polishing abrasive grains 36 while supplying the polishing fluid (silicon polishing composition) 26 that does not contain the polishing abrasive grains, the reactivity with the silicon is enhanced under the strong alkalinity of the organic amine, resulting in high polishing efficiency, because the polishing fluid 26 contains the organic amine and the water, and the polishing fluid 26 has the pH of 10.6 to 12.8.

Further, in the polishing method of the present embodiment and the polishing fluid 26 used for the polishing method, the polishing fluid 26 contains the inorganic alkaline agent in addition to the organic amine and the water, and the inorganic alkaline agent is the ammonium hydroxide having the concentration not higher than 2.82 mol/l or the potassium hydroxide having the concentration not higher than 0.93 mol/l. Thus, it is possible to maintain a stable and strong alkalinity, thereby further enhancing the reactivity with the workpiece (silicon wafer) 16 and resulting in higher polishing efficiency. At the same time, as the inorganic alkaline agent, the ammonium hydroxide having the concentration not higher than 2.82 mol/l (10%) that is below a range of the concentration considered to be deleterious, or the potassium hydroxide having the concentration not higher than 0.93 mol/l (5%) is used whereby risk is reduced in a polishing work environment.

Further, in the polishing method of the present embodiment and the polishing fluid 26 used for the polishing method, the concentration of the inorganic alkaline agent contained in the polishing fluid 26 is 0.030 to 0.100 mol/l. Thus, since a stable strong alkalinity is maintained, the reactivity with the workpiece (silicon wafer) 16 is further enhanced, thereby resulting in higher polishing efficiency while simultaneously reducing the risk in the polishing work environment.

Further, in the polishing method of the present embodiment and the polishing fluid 26 used for the polishing method, the organic amine contained in the polishing fluid 26 is 0.025 to 0.100 mol/l. Thus, the reactivity with the workpiece (silicon wafer) 16 is enhanced under the strong alkalinity of the organic amine, thereby resulting in high polishing efficiency.

Further, in the polishing method of the present embodiment and the polishing fluid 26 used for the polishing method, the organic amine contained in the polishing fluid 26 is the substance having the primary amine and/or the secondary amine. Thus, the organic amine becomes strongly alkaline when being dissolved in water.

Further, in the polishing method of the present embodiment and the polishing fluid 26 used for the polishing method, the organic amine contained in the polishing fluid 26 is ethylenediamine, piperazine or diethylenetriamine. Thus, the organic amine becomes strongly alkaline when being dissolved in water.

Further, in the polishing method of the present embodiment and the polishing fluid 26 used for the polishing method, the polishing abrasive grains 36 contained in the polishing pad 18 as the abrasive-grain polishing pad are silica, ceria, zirconia, alumina, silicon carbide, titania, manganese compounds, barium carbonate, chromium oxide and/or iron oxide. Thus, an appropriate polishing efficiency can be obtained.

While the embodiment of the present invention has been described in detail with reference to the drawings, the present invention is not limited to details of the embodiment but may be embodied also in other forms.

For example, in the flat surface polishing machine 10 in the above-described embodiment, the workpiece 16, whish is disposed on the polishing pad 18 rotated around the rotation axis C1, is rotated around the rotation axis C2 parallel to the rotation axis C1. However, the polishing process may be performed while the workpiece 16 is rotated and revolved by revolving the rotation axial C2 of the workpiece 16 along an orbit around a revolution axis parallel to the rotation axis C1.

Further, the base material resin 40 is made of epoxy resin or PES resin. However, the base material resin 40 may also be made of other resins, such as rigid foamed polyurethane resin, polyamide, polyamideimide, polyimide, polyacrylonitrile, polyvinylidene fluoride, cellulose acetate, polyvinyl alcohol, polyester, polyolefin resin, and/or non-foamed polyurethane.

Further, as the silica used in the above-described polishing abrasive grains 26, for example, fumed silica (fine silica grains obtained by burning silicon tetrachloride, chlorosilane, etc. at a high temperature in presence of hydrogen and oxygen) is preferably used.

Although not specifically illustrated, the present invention can be used with various modifications without departing from the spirit of the invention.

### DESCRIPTION OF REFERENCE SIGNS

10: polishing machine
12: polishing plate
16: workpiece (silicon wafer)
18: polishing pad
20: holding disc
26: polishing fluid (silicon polishing composition)
36: polishing abrasive grains

1. A silicon polishing method for polishing a silicon wafer by using an abrasive-grain polishing pad that contains polishing abrasive grains while supplying a silicon polishing composition that does not contain the polishing abrasive grains, wherein
the silicon polishing composition contains an organic amine and a water, and
the silicon polishing composition has a pH of 10.6 to 12.8.

2. The silicon polishing method according to claim 1, wherein
the silicon polishing composition contains an inorganic alkaline agent in addition to the organic amine and the water, and
the inorganic alkaline agent is ammonium hydroxide having a concentration not higher than 2.82 mol/l or potassium hydroxide having a concentration not higher than 0.93 mol/l.

3. The silicon polishing method according to claim 2, wherein the concentration of the inorganic alkaline agent is 0.030 to 0.100 mol/l.

4. The silicon polishing method according to claim 1, wherein the organic amine is 0.025 to 0.100 mol/l.

5. The silicon polishing method according to claim 1, wherein the organic amine is a substance having a primary amine and/or a secondary amine.

6. The silicon polishing method according to claim 5, wherein the organic amine is ethylenediamine, piperazine or diethylenetriamine.

7. The silicon polishing method according to claim 1, wherein the polishing abrasive grains contained in the abrasive-grain polishing pad are silica, ceria, zirconia, alumina and/or silicon carbide.

8. A silicon polishing composition, which is to be supplied onto an abrasive-grain polishing pad containing polishing abrasive grains when a silicon wafer is polished by using the abrasive-grain polishing pad, wherein
the silicon polishing composition contains an organic amine and a water, and
the silicon polishing composition has a pH of 10.6 to 12.8.

9. The silicon polishing composition according to claim 8, wherein
the silicon polishing composition contains an inorganic alkaline agent in addition to the organic amine and the water, and
the inorganic alkaline agent is ammonium hydroxide having a concentration not higher than 2.82 mol/l or potassium hydroxide having a concentration not higher than 0.93 mol/l.

10. The silicon polishing composition according to claim 9, wherein the concentration of the inorganic alkaline agent is 0.030 to 0.100 mol/l.

11. The silicon polishing composition according to claim 8, wherein the organic amine is 0.025 to 0.100 mol/l.

12. The silicon polishing composition according to claim 8, wherein the organic amine is a substance having primary amine and/or secondary amine.

13. The silicon polishing composition according to claim 8, wherein the organic amine is ethylenediamine, piperazine or diethylenetriamine.
